(19) United States
(12) Patent Application Publication
(10) Pub. No.: US 2021/0202244 A1
(43) Pub. Date: Jul. 1, 2021

(54) HIGH-THROUGHPUT MULTI-STAGE MANUFACTURING PLATFORM AND METHOD FOR PROCESSING A PLURALITY OF SUBSTRATES

(71) Applicant: Tokyo Electron Limited, Tokyo (JP)

(72) Inventor: Kandabara N. Tapily, Albany, NY (US)

(21) Appl. No.: 17/130,083

(22) Filed: Dec. 22, 2020

Related U.S. Application Data
(60) Provisional application No. 62/955,284, filed on Dec. 30, 2019.

(51) Int. Cl. H01L 21/02; H01L 21/311

(52) U.S. Cl. CPC H01L 21/02304; H01L 21/31116; H01L 21/02271

(57) ABSTRACT

A high-throughput manufacturing platform and a method for processing semiconductor substrates using the platform. The platform includes a plurality of process modules that include a first process module configured for performing a blocking layer deposition process, a second process module configured for performing a film deposition process, and a third process module configured for performing an etch process, where the blocking layer deposition process requires a longer processing time for each substrate than the film deposition process and the etch process, and where the first process module is configured for simultaneously processing a greater number of substrates than the second and third process modules. A substrate metrology module is hosted on the platform, the substrate metrology module includes an inspection system operable for measuring data associated with an attribute of a substrate at least one of before or after the substrate is processed in a process module of the platform.

### CROSS-REFERENCE TO RELATED APPLICATIONS

This application claims priority to U.S. Provisional Patent Application No. 62/955,284, entitled, “High Throughput Multi-stage Processing Platform and Method for Processing a Plurality of Substrates,” filed Dec. 30, 2019; the disclosure of which is expressly incorporated herein, in its entirety, by reference.

### FIELD OF THE INVENTION

The present invention relates to semiconductor processing and semiconductor manufacturing platforms.

### BACKGROUND OF THE INVENTION

Self-aligned patterning needs to replace overlay-driven patterning so that cost-effective scaling can continue even after EUV introduction. Patterning options that enable reduced variability, extend scaling and enhanced CD and process control are needed. However, it is getting extremely difficult to produce scaled devices at reasonably low cost.

Selective deposition can significantly reduce the cost associated with advanced patterning. Selective deposition of thin films such as gap fill, area selective deposition of dielectrics and metals on specific materials, and selective hard masks are key steps in patterning in highly scaled technology nodes. High-volume manufacturing of semiconductor devices includes several selective deposition steps that must be performed on high-throughput process modules and platforms.

### SUMMARY OF THE INVENTION

A method for high-throughput semiconductor processing and a high-throughput manufacturing platform for fabrication of electronic devices on a plurality of substrates is described in several embodiments.

According to one embodiment, a manufacturing platform for fabrication of electronic devices on a plurality of substrates is described, the manufacturing platform comprising a plurality of process modules hosted on the manufacturing platform, the plurality of process modules configured for manipulating materials on the plurality of substrates in processing steps as part of a processing sequence. The plurality of process modules include a first process module configured for performing a blocking layer deposition process, a second process module configured for performing a film deposition process, and a third process module configured for performing an etch process, where the blocking layer deposition process requires a longer processing time for each substrate than the film deposition process and the etch process, and where the first process module is configured for simultaneously processing a greater number of substrates than the second and third process modules. The platform further includes at least one substrate metrology module hosted on the manufacturing platform, the substrate metrology module including an inspection system operable for measuring data associated with an attribute of a substrate at least one of before or after the substrate is processed in a process module of the manufacturing platform, and at least one substrate transfer system hosted on the manufacturing platform and configured for the movement of the plurality of substrates between the plurality of process modules and the at least one metrology module.

According to one embodiment, method for fabrication of electronic devices on a plurality of substrates in a manufacturing platform is described, the method includes providing a plurality of substrates in a plurality of process modules hosted on the manufacturing platform, the process modules configured for manipulating materials on the plurality of substrates in processing steps as part of a processing sequence, performing a blocking layer deposition process in a first process module, performing a film deposition process in a second process module, and performing an etch process in a third process module, where the blocking layer deposition process requires a longer processing time for each substrate than the film deposition process and the etch process, and where the first process module is configured for simultaneously processing a greater number of substrates than the second and third process modules. The method further includes performing substrate metrology on a substrate in a metrology module hosted on the manufacturing platform, the substrate metrology module including an inspection system operable for measuring data associated with an attribute of a substrate at least one of before or after the substrate is processed in a process module of the manufacturing platform, and using at least one substrate transfer system hosted on the manufacturing platform for the movement of the plurality of substrates between the plurality of process modules and the at least one metrology module.

### BRIEF DESCRIPTION OF THE DRAWINGS

A more complete appreciation of embodiments of the invention and many of the attendant advantages thereof will become readily apparent with reference to the following detailed description, particularly when considered in conjunction with the accompanying drawings, in which:

FIG. 1 shows a high-throughput multistage manufacturing platform according to an embodiment of the invention;

FIGS. 2A-2E show a schematic illustration of a semiconductor fabrication process flow according to an embodiment of the invention;

FIG. 3 is a process flow for a semiconductor fabrication process according to an embodiment of the invention;

FIG. 4 is a process flow for a semiconductor fabrication process according to an embodiment of the invention;

FIG. 5A schematically shows through a cross-sectional view a process module of a high-throughput multistage manufacturing platform according to an embodiment of the invention; and

FIG. 5B schematically shows through a cross-sectional view a process module of a high-throughput multistage manufacturing platform according to an embodiment of the invention.

### DETAILED DESCRIPTION OF SEVERAL EMBODIMENTS

Embodiments of the disclosure describe a method for high-throughput semiconductor processing and a high-throughput manufacturing platform that may be used for the processing.

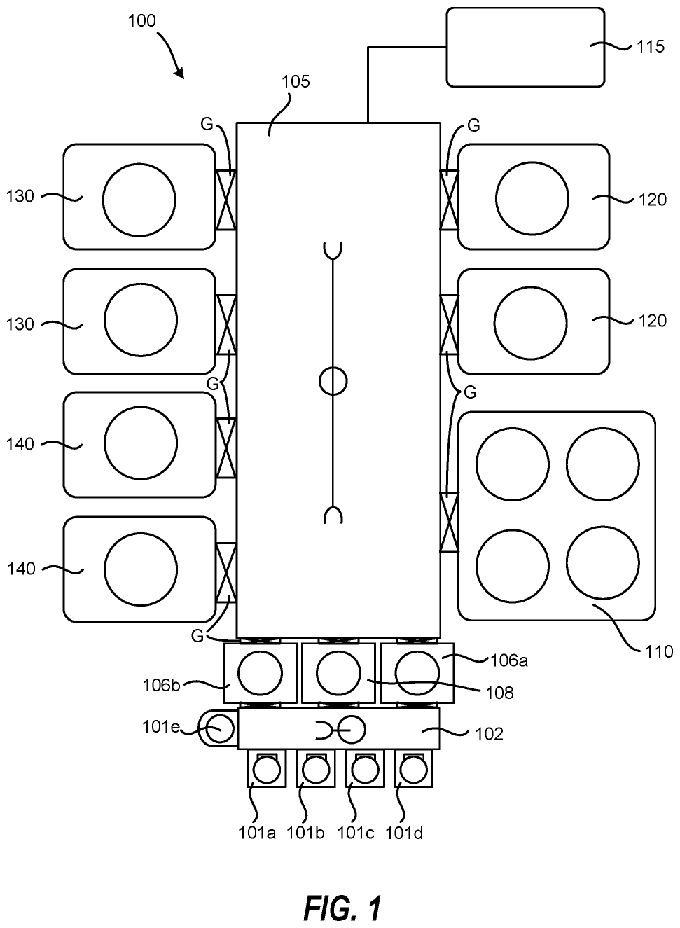

FIG. 1 shows an exemplary high-throughput multistage manufacturing platform 100 suitable for practicing embodiments of the invention. The manufacturing platform 100 incorporates multiple modules and processing tools for the processing of semiconductor substrates for the fabrication of integrated circuits and other devices. This includes one or more substrate metrology modules that are incorporated within the manufacturing platform 100 along with the process modules. For example, the manufacturing platform 100 may incorporate a plurality of process modules that are coupled to a substrate transfer module as shown. In some embodiments, a substrate metrology module or tool is also positioned, at least partially, inside the substrate transfer module. As such, a substrate may be processed and then transferred immediately to a substrate metrology module in order to collect various fabrication data associated with attributes of the substrate that is further processed by a process control system. The process control system gathers data from the processing and substrate metrology modules and controls a process sequence that is executed on the manufacturing platform 100 through the selective movement of the substrate and control of one or more of the plurality of process modules. Furthermore, the manufacturing platform 100 may transfer a substrate inside the chamber of the transfer module and between the various process modules and the substrate metrology modules without leaving the controlled environment of the chamber. The process control system controls the sequential process flow through the various process modules utilizing information that is derived from substrate measurements obtained from the one or more substrate metrology modules. Furthermore, the process control system incorporates process modules in-situ measurements and data to control the sequential process flow through the manufacturing platform 100. The on-substrate measurement data obtained in the controlled environment may be utilized alone or in combination with the in-situ process module measurement data for process flow control and improvement of the process in accordance with embodiments of the invention.

Still referring to FIG. 1, the system of manufacturing platform 100 contains a front-end substrate transfer module 102 to introduce substrates to the system. The exemplary manufacturing platform 100 represents a plurality of process modules organized around the periphery of the central substrate transfer module 105. The system of manufacturing platform 100 includes cassette modules 101a, 101b, 101c, 101d and an alignment module 101e for aligning the orientation of the substrates. Load-lock chambers 106a and 106b are also coupled to the front-end substrate transfer module 102 through gate valves. The front-end substrate transfer module 102 is generally maintained at atmospheric pressure but a clean environment may be provided by purging with an isolation gas containing an inert gas. Load-lock chambers 106a and 106b are coupled to the central substrate transfer module 105 and may be used for transferring substrates from the front-end substrate transfer module 102 to the central substrate transfer module 105 for processing substrate in the manufacturing platform 100.

The central substrate transfer module 105 may be maintained at a very low base pressure (e.g., 5×10⁻⁸ Torr, or lower) or constantly purged with an inert gas. In accordance with the embodiments of the invention, a substrate metrology module 108 may be operated under atmospheric pressure or operated under vacuum conditions. In accordance with one embodiment, the substrate metrology module 108 is kept at vacuum conditions and the substrates are processed in the manufacturing platform 100 and measured without leaving vacuum. As disclosed further herein, the substrate metrology module 108 may include one or more inspection systems or analytical tools that are capable of measuring one or more material properties or attributes of a substrate and/or of the thin films and layers deposited on the substrates or the devices formed on the substrates. As used herein, the term “attribute” is used to indicate a measurable feature or property of a substrate, layer on a substrate, feature or device on a substrate, etc., that is reflective of the processing quality of the processing sequence. The measured data associated with an attribute is then used to adjust the process sequence by analyzing the measured data along with other in-situ processing data through the process control system. For example, the measured attribute data reflects non-conformities or defects on the substrate for providing corrective processing.

The exemplary manufacturing platform 100 in FIG. 1 shows a single substrate metrology module 108. However, the manufacturing platform 100 may incorporate a plurality of such substrate metrology modules that are incorporated around one or more substrate transfer systems, such as the central substrate transfer module 105. Such substrate metrology modules may be stand-alone modules that are accessed through the central substrate transfer module 105 like a process module. Such stand-alone modules will generally incorporate inspection systems therein that are configured to engage a substrate that is positioned in a measurement region of the module and to measure data associated with an attribute of the substrate.

In an alternative embodiment of the invention, a substrate metrology module 108 may be implemented in a measurement region located within a dedicated area of an internal space of the chamber defined by the substrate substrate metrology module 108. Still further, a substrate metrology module 108 may be incorporated wherein at least a portion of the substrate metrology module 108 is positioned inside of an internal space of a central substrate transfer module 105, and other components of the substrate metrology module 108 or the specific inspection system of the substrate metrology module 108 are incorporated outside of the central substrate transfer module 105 and interfaced through an aperture or window into a dedicated area of the internal space that forms the measurement region in which a substrate is located or through which a substrate will pass.

The substrate metrology module 108 includes one or more inspection systems that are operable for measuring data associated with an attribute of the substrate. Such data may be associated with one or more attributes that reflect the quality of the processing sequence and the quality of the layers and features and devices that are being formed on a substrate. The collected measurement data is then analyzed, along with process module data, by a process control system for detecting various non-conformities and/or defects on the substrate or substrate layers/features. The system then provides for corrective processing of the substrate, such as in upstream or downstream process modules in the process sequence to ameliorate/correct the non-conformities or defects and improve the overall process.

In accordance with embodiments of the invention, the measurements taken by the substrate metrology module 108 or inspection systems thereof and the data generated is associated with one or more attributes of a substrate. For example, the attribute measured may include, for example, on or more of: a layer thickness, a layer conformality, a layer coverage, or a layer profile of a layer on the substrate, a property relating to selective deposition process(es), a property relating to selective etch process(es), or some combination thereof associated with the fabricated electronic devices on the substrate. The list of measured attributes for generating measurement data for the invention is not limited and could include other attribute data that might be used for processing a substrate and fabricating devices.

The substrate metrology modules and/or inspections systems used for providing attribute data may implement a number of tools and methods for measurement for providing the measurement and metrology. The substrate metrology modules and/or inspections systems may include optical methods, including high-resolution optical imaging and microscopy (e.g., bright-field, dark-field, coherent/incoherent/partially coherent, polarized, Nomarski, etc.), hyperspectral (multi-spectral) imaging, interferometry (e.g., phase shifting, phase modulation, differential interference contrast, heterodyne, Fourier transform, frequency modulation, etc.), spectroscopy (e.g., optical emission, light absorption, various wavelength ranges, various spectral resolutions, etc.), Fourier transform Infrared spectroscopy (FTIR) reflectometry, scatterometry, spectroscopic ellipsometry, polarimetry, refractometers, etc. For example, the inspection system used for measuring data that is associated with an attribute of the substrate may use one or more of the following techniques or devices: optical thin film measurement, such as reflectometry, interferometry, scatterometry, profilometry, ellipsometry; X-Ray measurements, such as X-ray photo-emission spectroscopy (XPS), X-Ray fluorescence (XRF), X-Ray diffraction (XRD), X-Ray reflectometry (XRR); ion scattering measurements, such as ion scattering spectroscopy, low energy ion scattering (LEIS) spectroscopy, auger electron spectroscopy, secondary ion mass spectroscopy, and reflection absorption IR spectroscopy. The list of measurement techniques or devices for generating measurement data for the invention is not limited and could include other techniques or devices that might be used for obtaining the useful data for processing a substrate and fabricating devices in accordance with the invention.

Still referring to FIG. 1, coupled to the substrate metrology module 108 are a plurality of process modules 110-140 that are configured for processing substrates, such as semiconductor or silicon (Si) substrates. The Si substrates can, for example, have a diameter of 150 mm, 200 mm, 300 mm, 450 mm, or larger than 450 mm. The various process modules and substrate metrology modules all interface with the central substrate transfer module 105 through appropriate gate access ports with valves, for example. According to one embodiment of the invention, a first process module 110 may form a blocking layer (e.g., a self-aligned monolayer (SAM)) on a portion of a substrate, the second process module(s) 120 may deposit a film on a substrate by a suitable deposition process, the third process module(s) 130 may perform an etching process on a substrate where material is removed from the substrate, and the fourth process module(s) 140 may perform a treatment or cleaning process on a substrate.

The central substrate transfer module 105 is configured for transferring substrates between any of the process modules 110-140 and then into the substrate metrology module 108 either before or after a particular processing step. Gate valves G that provide isolation at the access ports between adjacent processing chambers/tool components. As depicted in the embodiment of FIG. 1, the process modules 110-140 and the substrate metrology module 108 may be directly coupled to the central substrate transfer module 105 by the gate valves G and such direct coupling can greatly improve substrate throughput in accordance with the invention.

The manufacturing platform 100 includes one or more controllers or control system that can be coupled to control the various process modules and associated process modules/tools depicted in FIG. 1 during the integrated processing and metrology process as disclosed herein. The process control system 115 can be coupled to one or more additional controllers/computers/databases (not shown) as well. Process control system 115 can obtain setup and/or configuration information from an additional controller/computer or a server over a network. The process control system 115 is used to configure and run any or all of the process modules and processing tools and to gather data from the various substrate metrology modules and in-situ data from the process modules. The process control system 115 collects, provides, processes, stores, and displays data from any or all of the process modules and tool components. The process control system 115 can comprise a number of different programs and applications and processing engines to analyze the measured data and in-situ processing data and to implement algorithms, such as deep learning networks, machine learning algorithms, autonomous learning algorithms and other algorithms for providing the active control.

The process control system 115 can be implemented in one or more computer devices having a microprocessor, suitable memory, and digital I/O port and is capable of generating control signals and voltages that are sufficient to communicate, activate inputs to the various modules of the manufacturing platform 100, and exchange information with the processing systems run on the manufacturing platform 100. The process control system 115 monitors outputs from the manufacturing platform 100 as well as measured data from the various substrate metrology modules of the manufacturing platform 100. For example, a program stored in the memory of the process control system 115 may be utilized to activate the inputs to the various processing systems and transfer systems according to a process recipe or sequence in order to perform desired integrated processing.

The process control system 115 also uses measured data as well as in-situ processing data output by the process modules to detect non-conformities or defects in the substrate and provide corrective processing. The process control system 115 may be implemented as a general purpose computer system that performs a portion or all of the microprocessor based processing steps of the invention in response to a processor executing one or more sequences of one or more instructions contained in a program in memory. Such instructions may be read into the control system memory from another computer readable medium, such as a hard disk or a removable media drive. One or more processors in a multi-processing arrangement may also be employed as the control system microprocessor element to execute the sequences of instructions contained in memory. In alternative embodiments, hard-wired circuitry may be used in place of or in combination with software instructions for implementing the invention. Thus, embodiments are not limited to any specific combination of hardware circuitry and software for executing the metrology driver processes of the invention as discussed herein.

The process control system 115 may be locally located relative to the manufacturing platform 100, or it may be remotely located relative to the manufacturing platform 100. For example, the process control system 115 may exchange data with the manufacturing platform 100 using at least one of a direct connection, an intranet connection, an Internet connection and a wireless connection. The process control system 115 may be coupled to an intranet at, for example, a customer site (i.e., a device maker, etc.), or it may be coupled to an intranet at, for example, a vendor site (i.e., an equipment manufacturer). Additionally, for example, the process control system 115 may be coupled to other systems or controls through an appropriate wired or wireless connection. Furthermore, another computer (i.e., controller, server, etc.) may access, for example, the process control system 115 to exchange data via at least one of a direct wired connection or a wireless connection, such as an intranet connection, and/or an Internet connection. As also would be appreciated by those skilled in the art, the process control system 115 will exchange data with the modules of the manufacturing platform 100 via appropriate wired or wireless connections. The process modules may have their own individual control systems (not shown) that take input data for control of the processing chambers and tools and sub-systems of the modules and provide in-situ output data regarding the process parameters and metrics during processing sequence.

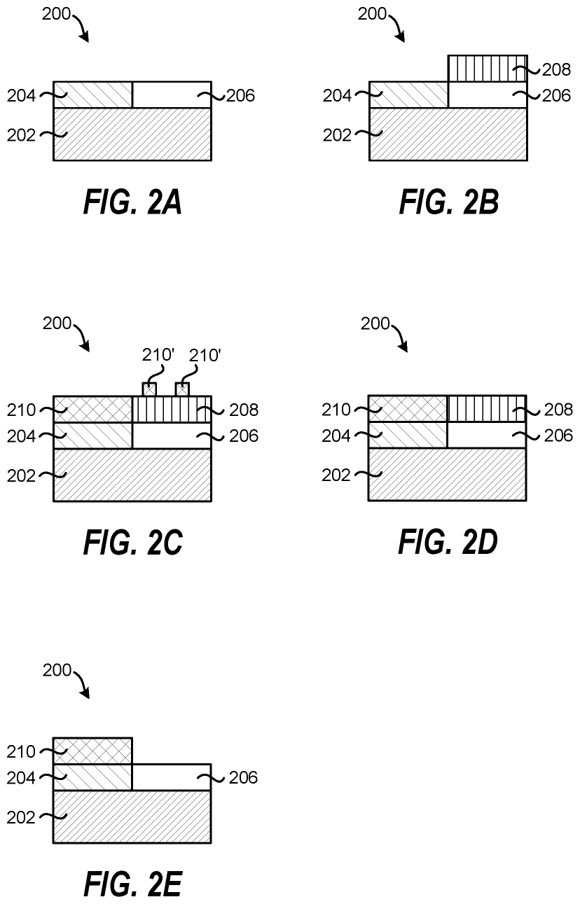

FIGS. 2A-2E show a schematic illustration of a semiconductor fabrication process flow according to an embodiment of the invention. A substrate 200 is provided in the high-throughput multi-stage manufacturing platform 100 in FIG. 1 that contains a plurality of process modules, each process module configured for performing one or more process steps. One or more of the process modules may be configured for simultaneously processing a plurality of substrates. The substrate 200 can contain different materials commonly found in integrated circuits, including metals, metal-containing materials, dielectric materials, and semiconductor materials. Two or more of the different materials may have exposed surfaces where selective film formation is required for patterning in highly scaled technology nodes.

In one example, schematically shown in FIG. 2A, the substrate 200 can include a base film 202 and an exposed surface of a first material layer 204 and an exposed surface of a second material layer 206. In one example, the first material layer 204 includes a dielectric material and the second material layer 206 includes a metal layer. The dielectric material 204 can, for example, contain SiO₂, a low dielectric constant (low-k) material such as fluorinated silicon glass (FSG), carbon doped oxide, a polymer, a SiCOH-containing low-k material, a non-porous low-k material, a porous low-k material, a CVD low-k material, a spin-on dielectric (SOD) low-k material, a nitride material, a dielectric material containing an airgap, or any other suitable dielectric material, including a high dielectric constant (high-k) material. The metal layer can, for example, include Ru metal, Co metal, Cu metal, Mo metal, Ni metal, Al metal, Ir metal, Nb metal, Re metal, W metal, or a combination of thereof.

Once inside the central substrate transfer module 105, the substrate 200 may be transferred into one of the process modules 110-140 for treating with a treatment gas. In one example, the fourth process module(s) 140 may be dedicated for performing a treatment process or cleaning process on the substrate 200. The treating may be performed in order to remove surface impurities and contaminants, and provide a desired surface termination for the next processing step(s). The treating can, for example, include exposure to plasma-excited H₂ gas, plasma-excited Ar gas, substrate heating, or a combination thereof. The treating can include exposure to process gases (e.g., NH₃, N₂H₄, CO, or H₂) that remove surface oxidation and chemically reduce a surface of a metal layer and clean a surface of a dielectric material.

Thereafter, a plurality of substrates 200 are transferred into the first process module 110 that is configured for simultaneously processing the plurality of substrates 200, for example four substrates, or more. The first process module 110 may be configured for simultaneously exposing the plurality of substrates 200 to a reactant gas capable of forming a blocking layer on the plurality of substrates 200.

According to one embodiment, a blocking layer containing a self-aligned monolayer (SAM) is formed on the plurality of substrates 200. The SAM may be formed on the plurality of substrates 200 by exposure to a reactant gas containing a molecule that is capable of forming a SAM on the substrate. The SAM is a molecular assembly that is spontaneously formed on substrate surfaces by adsorption and organized into more or less large ordered domains. The SAM can include a molecule that possesses a head group, a tail group, and a functional end group, and the SAM is created by the chemisorption of head groups onto the substrate surface from the vapor phase at room temperature or above room temperature, followed by a slow organization of the tail groups. Initially, at small molecular density on the surface, adsorbate molecules form either a disordered mass of molecules or form an ordered two-dimensional “lying down phase”, and at higher molecular coverage, over a period of minutes to hours, begin to form three-dimensional crystalline or semi-crystalline structures on the substrate surface. The head groups assemble together on the substrate, while the tail groups assemble far from the substrate.

According to one embodiment, the head group of the molecule forming the SAM can include a thiol, a silane, or a phosphonate. Examples of silanes include molecule that include C, H, Cl, F, and Si atoms, or C, H, Cl, and Si atoms. Nonlimiting examples of the molecule include octadecyltrichlorosilane (CH₃(CH₂)₁₇SiCl₃), octadecylthiol (CH₃(CH₂)₁₇SH), octadecyl phosphonic acid (CH₃(CH₂)₁₇P(O)(OH)₂), perfluorodecyltrichlorosilane (CF₃(CF₂)₇CH₂CH₂SiCl₃), perfluorodecanethiol (CF₃(CF₂)₇CH₂CH₂SH), chlorodecyldimethylsilane (CH₃(CH₂)₈CH₂Si(CH₃)₂Cl), and tertbutyl(chloro)dimethylsilane ((CH₃)₃CSi(CH₃)₂Cl)).

The presence of the SAM on a substrate 200 may be used to enable subsequent selective film formation on the first material layer 204 (e.g., a dielectric layer) relative to the second material layer 206 (e.g., a metal layer). This selective deposition behavior provides an effective method for selectively depositing a film on the first material layer 204 while preventing or reducing film deposition on the second material layer 206. It is speculated that the SAM density is greater on the second material layer 206 relative to on the first material layer 204, possibly due to higher initial ordering of the molecules on the second material layer 206 relative to on the first material layer 204. This greater SAM density on the second material layer 206 is schematically shown as SAM 208 in FIG. 2B. In another example, a different reactant gas may be used that selectively forms a SAM on the first material layer 204 relative to on the second material layer 206, thereby enabling selectively depositing a film on the second material layer 206 while preventing or reducing film deposition on the first material layer 204.

The formation of the SAM 208 on the substrate 200, in particular the slow organization of the tailgroups on the substrate, over a period of minutes to hours, is likely the slowest step in a process sequence performed on the manufacturing platform 100. Embodiments of the invention address this problem in high-volume manufacturing of semiconductor devices by configuring the first process module 110 that forms the SAM 208 (or another type of blocking layer) to simultaneously process a plurality of substrates 200, where the plurality of substrates 200 are present in the first process module 110 at the same time, in order to achieve the desired substrate throughput, despite the long processing time. Thus, the first process module 110 can hold and simultaneously process a greater number of substrates than the second, third, and fourth process modules 120-140.

Following the formation of the SAM 208, the substrate 200 may optionally be subjected to in-situ metrology in the substrate metrology module 108, where the extent or quality of the SAM 208 on the substrate 200 is measured and evaluated.

Thereafter, the substrate 200 is transferred into the second process module 120 where a film 210 is substantially selectively deposited by gas phase deposition on a surface of a material that is not blocked by the SAM 208. This is schematically shown in FIG. 2C, where a film 210 (e.g., a dielectric film) is deposited on the first material layer 204, and a small amount of undesired film nuclei 210′ are deposited on the second material layer 206 containing the SAM 208. The amount of the film nuclei 210′ is less than the amount of the film 210 on the first material layer 204. Thereafter, the substrate 200 may be subjected to in-situ metrology in the substrate metrology module 108, where the selectivity of the film deposition on the different materials of the substrate 200 is measured. The in-situ metrology step may be used to determine the amount of subsequent etching needed to remove the film nuclei 210′ from the SAM 208, while only etching a portion of the film 210 on the first material layer 204.

Thereafter, the substrate 200 may be transferred to the third process module 130 for performing a dry etching process that removes the film nuclei 210′ from the SAM 208, thereby selectively forming the film 210 on the first material layer 204 relative to on the SAM 208 and the second material layer 206. This is schematically shown in FIG. 2D. Thereafter, the substrate 200 may be subjected to in-situ metrology in the substrate metrology module 108, where the extent of the etching of the film nuclei 210′ is measured. The in-situ metrology step may be used to determine if the amount of etching need to be reduced or increased to effectively remove the film nuclei 210′ from the SAM 208.

Following the dry etching process and the optional metrology step, the substrate may be transferred to the fourth process module 140 for removing the SAM 208 from the substrate 200. This is schematically shown in FIG. 2E. For example, the SAM 208 may be removed by gas phase exposure, substrate heating, or both.

Thereafter, the above processing steps (treating, SAM formation, film deposition, dry etching, SAM removal, and metrology) may be repeated as needed to increase a thickness of the film 210 that is selectively formed on the first material layer 204.

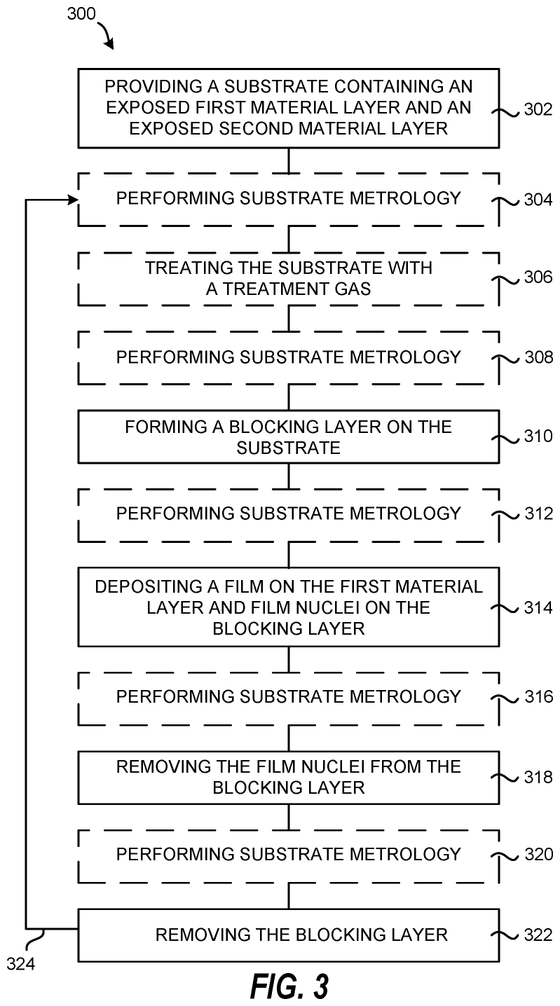

FIG. 3 is a process flow for a semiconductor fabrication process according to an embodiment of the invention. The process flow 300 includes, in 302, providing a substrate containing an exposed first material layer and an exposed second material layer, and in 304, optionally performing substrate metrology for measuring data associated with an attribute of the substrate. In 306, the process flow includes optionally treating the substrate with a treatment gas, and in 308, optionally performing substrate metrology. In 310, the process flow includes forming a blocking layer on the substrate, and in 312, optionally performing substrate metrology. In 314, the process flow includes depositing a film on the first material layer and film nuclei on the second material layer, and in 316, optionally performing substrate metrology. In 318, the process flow includes removing the film nuclei from the blocking layer, in 320, optionally performing substrate metrology, and in 322, removing the blocking layer from the substrate. Thereafter, as shown by process arrow 324, steps 304-322 may be repeated to increase a thickness of the film on the first material layer.

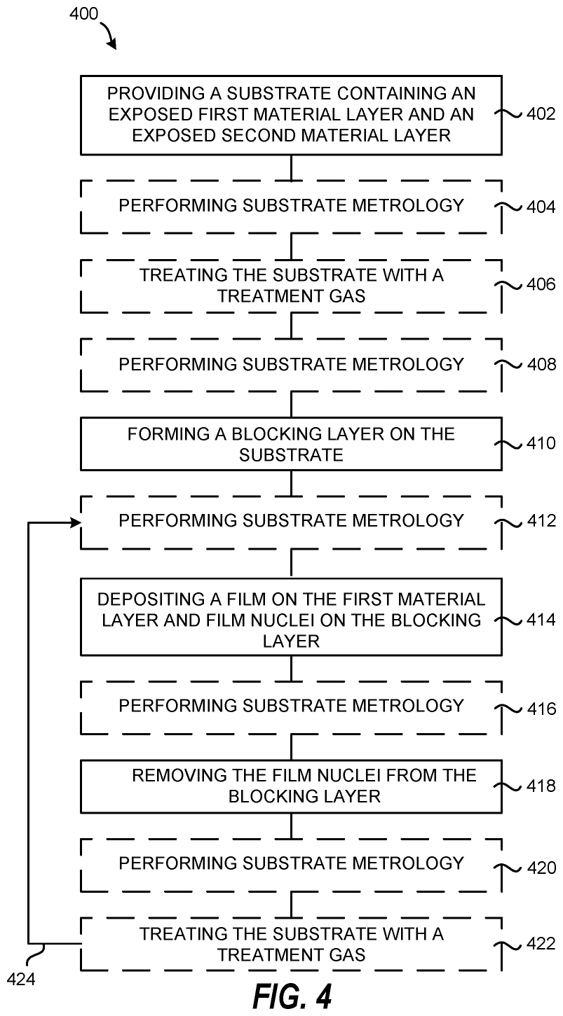

FIG. 4 is a process flow for a semiconductor fabrication process according to an embodiment of the invention. The process flow 300 includes, in 402, providing a substrate containing an exposed first material layer and an exposed second material layer, and in 404, optionally performing substrate metrology for measuring data associated with an attribute of the substrate. In 406, the process flow includes optionally treating the substrate with a treatment gas, and in 408, optionally performing substrate metrology. In 410, the process flow includes forming a blocking layer on the substrate, and in 412, optionally performing substrate metrology. In 414, the process flow includes depositing a film on the first material layer and film nuclei on the second material layer, and in 416, optionally performing substrate metrology. In 418, the process flow includes removing the film nuclei from the blocking layer, in 420, optionally performing substrate metrology, and in 422, removing the blocking layer from the substrate. Thereafter, as shown by process arrow 424, steps 412-422 may be repeated to increase a thickness of the film on the first material layer.

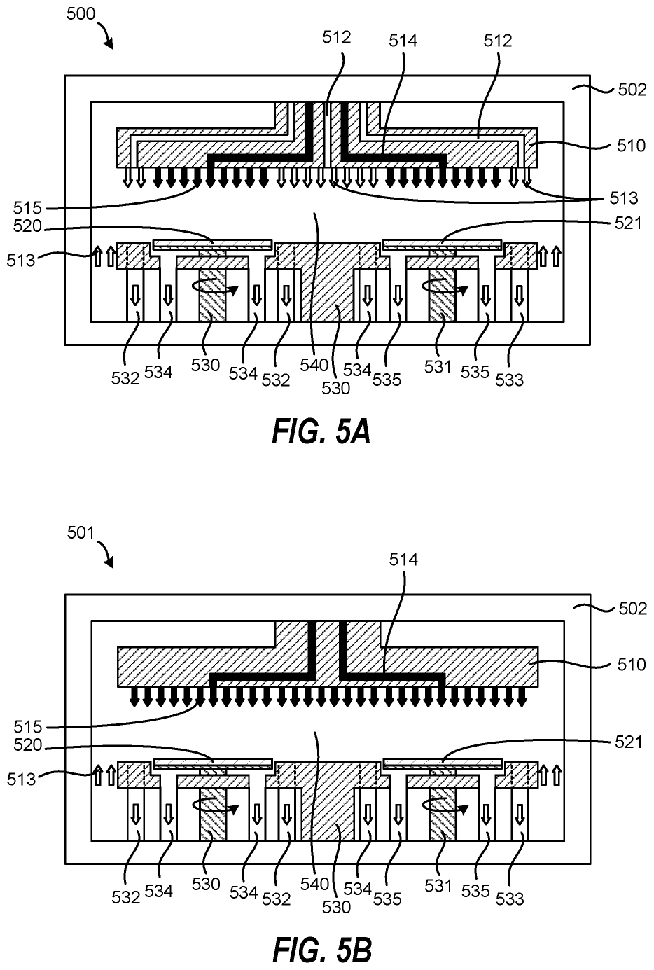

FIG. 5A schematically shows through a cross-sectional view a process module of a high-throughput multistage manufacturing platform according to an embodiment of the invention. The process module 500 is an example of the process module 110 in FIG. 1, and may be used to simultaneously process and form a blocking layer on a plurality of substrates. The process module 500 includes a chamber 502, and a showerhead 510 containing first gas lines 514 for introducing a first process gas 515 into a processing space 540, and second gas lines 512 for introducing a second process gas 513 into the processing space 540. The single showerhead 510 shown in FIG. 5A may be used to simultaneously expose the multiple substrates mounted a multi-zone substrate holder platform 530 to the process gases. Alternatively, multiple showerheads (e.g., one showerhead per substrate) may be used. The process module 500 is equipped with a gate valve (not shown) to isolate the process module 500 from the rest of the manufacturing platform 100. Further, the multi-zone substrate holder platform 530 is positioned opposite the gas showerhead 510 and includes a plurality of substrate holders for supporting a plurality of substrates. The plurality of substrate holders can, for example include two, three, four, or more, substrate holders. The exemplary cross-sectional view in FIG. 5A shows rotatable substrate holders 530 and 531 that support substrates 520 and 521, respectively. Rotation of the substrate holder 530 and 531 may be carried out to improve film uniformity control. The process module 500 further includes a plurality of independent pumping lines 532, 533, 534, and 535 that are used to control the gas flow in the process module 500 and to offer different absorption times for each substrate, if desired. In one example, the first process gas 515 can include reactant gas containing a molecule that is capable of forming a SAM on the substrates 520 and 521, and the second process gas 513 can contain an inert gas. In this configuration, the inert gas forms a gas curtain between the substrate 520 and 521 for better controlling the reactant gas exposure for each substrate and improve control of the formation of the blocking layer.

FIG. 5B schematically shows through a cross-sectional view a process module of a high-throughput multistage manufacturing platform according to an embodiment of the invention. The process module 501 is similar to the process module 500 in FIG. 5B where the showerhead 511 contains first gas lines 514 for introducing the first process gas 515 into the processing space 540 but the second gas lines 512 for introducing the second process gas 513 into the processing space 540 are omitted.

A plurality of embodiments for a method for high-throughput semiconductor processing and a high-throughput manufacturing platform that may be used for the processing have been described. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A manufacturing platform for fabrication of electronic devices on a plurality of substrates, the manufacturing platform comprising:
a plurality of process modules hosted on the manufacturing platform, the plurality of process modules configured for manipulating materials on the plurality of substrates in processing steps as part of a processing sequence, the plurality of process modules including:
a first process module configured for performing a blocking layer deposition process;
a second process module configured for performing a film deposition process;
a third process module configured for performing an etch process, wherein the blocking layer deposition process requires a longer processing time for each substrate than the film deposition process and the etch process, and wherein the first process module is configured for simultaneously processing a greater number of substrates than the second and third process modules;
at least one substrate metrology module hosted on the manufacturing platform, the substrate metrology module including an inspection system operable for measuring data associated with an attribute of a substrate at least one of before or after the substrate is processed in a process module of the manufacturing platform; and
at least one substrate transfer system hosted on the manufacturing platform and configured for the movement of the plurality of substrates between the plurality of process modules and the at least one metrology module.

2. The platform of claim 1, further comprising at least one additional second process module for performing the film deposition process, at least one additional third process module for performing the etch process, or a combination thereof.

3. The platform of claim 1, wherein the first process module contains a showerhead configured for simultaneously exposing a first plurality of substrates to a reactant gas.

4. The platform of claim 3, wherein the showerhead further exposes the plurality of substrates to an isolation gas that provides an inert gas curtain between each of the first plurality of substrates.

5. The platform of claim 1, wherein the first process module contains a plurality of showerheads, wherein each showerhead is configured for exposing one of a first plurality of substrates to a reactant gas.

6. The platform of claim 5, wherein each showerhead further exposes the one of the first plurality of substrates to an isolation gas that provides an inert gas curtain between each of the first plurality of substrates.

7. The platform of claim 1, wherein the first process module contains a plurality of substrate holders, wherein each substrate holder is configured for supporting a substrate.

8. The platform of claim 7, wherein the plurality of substrate holders are configured for rotating the plurality of substrates.

9. The platform of claim 1, further comprising a fourth process module configured for removing the blocking layer from the plurality of substrates.

10. The platform of claim 1, wherein the blocking layer includes a self-assembled monolayer (SAM).

11. A method for fabrication of electronic devices on a plurality of substrates in a manufacturing platform, the method comprising:
providing a plurality of substrates in a plurality of process modules hosted on the manufacturing platform, the process modules configured for manipulating materials on the plurality of substrates in processing steps as part of a processing sequence;
performing a blocking layer deposition process in a first process module;
performing a film deposition process in a second process module;
performing an etch process in a third process module, wherein the blocking layer deposition process requires a longer processing time for each substrate than the film deposition process and the etch process, and wherein the first process module is configured for simultaneously processing a greater number of substrates than the second and third process modules;
performing substrate metrology on a substrate in a metrology module hosted on the manufacturing platform, the substrate metrology module including an inspection system operable for measuring data associated with an attribute of a substrate at least one of before or after the substrate is processed in a process module of the manufacturing platform; and
using at least one substrate transfer system hosted on the manufacturing platform for the movement of the plurality of substrates between the plurality of process modules and the at least one metrology module.

12. The method of claim 11, wherein the manufacturing platform comprises at least one additional second process module for performing the film deposition process, at least one additional third process module for performing the etch process, or a combination thereof.

13. The method of claim 11, further comprising:
simultaneously exposing a first plurality of substrates to the reactant gas using a showerhead in the first process module.

14. The method of claim 13, further comprising:
exposing the first plurality of substrates to an isolation gas that provides an inert gas curtain between each of the first plurality of substrates.

15. The method of claim 11, wherein the first process module contains a plurality of showerheads, wherein each showerhead is configured for exposing one of the first plurality of substrates to a reactant gas.

16. The method of claim 15, wherein each showerhead further exposes the of the first plurality of substrates to an isolation gas that provides an inert gas curtain between each of the first plurality of substrates.

17. The method of claim 11, wherein the first process module contains a plurality of substrate holders, wherein each substrate holder is configured for supporting a substrate.

18. The method of claim 17, wherein the plurality of substrate holders are configured for rotating the plurality of substrates.

19. The method of claim 11, further comprising a fourth process module configured for removing the blocking layer from the plurality of substrates.

20. The method of claim 11, wherein the blocking layer includes a self-assembled monolayer (SAM).
